(19) United States
(12) Patent Application Publication
(10) Pub. No.: US 2026/0182227 A1
(43) Pub. Date: Jun. 25, 2026

(54) DISPLAY COVER PLATE, DISPLAY MODULE, AND METHOD FOR MANUFACTURING THE SAME, AND DISPLAY DEVICE

(71) Applicant: BOE TECHNOLOGY GROUP CO., LTD., Beijing (CN)

(72) Inventors: Xuekai YANG, Beijing (CN); Ziang HAN, Beijing (CN); Paoming TSAI, Beijing (CN); Song ZHANG, Beijing (CN); Shijie FAN, Beijing (CN); Haitao LIU, Beijing (CN)

(21) Appl. No.: 18/836,675

(22) PCT Filed: Mar. 27, 2023
(86) PCT No.: PCT/CN2023/084155

§ 371 Date: Aug. 7, 2024

(51) Int. Cl. H10K 59/80; H10K 59/12; H10K 59/127; H10K 102/00

(52) U.S. Cl. CPC H10K 59/8791; H10K 59/1201; H10K 59/127; H10K 59/874; H10K 59/8793; H10K 2102/351

(57) ABSTRACT

A display cover plate and a method for manufacturing the same, a display module and a method for manufacturing the same, and a display device are provided. The display cover plate includes: an anti-reflection layer including an anti-reflection film and a first adhesive layer, at least a portion of the anti-reflection film having a curved-surface shape, and the first adhesive layer being located on a side of the convex surface of the anti-reflection film; and an injection layer having a curved-surface shape that matches with a curved-surface area of the anti-reflection film, a concave surface of the injection layer facing toward the first adhesive layer.

### CROSS REFERENCE TO RELATED APPLICATIONS

The present disclosure is the U.S. national phase application of International Application No. PCT/CN2023/084155 filed on Mar. 27, 2023, the content of which is incorporated herein by reference in its entirety for all purposes.

The present disclosure relates to the field of display technology, in particular, to a display cover plate and a method for manufacturing the same, a display module and a method for manufacturing the same, and a display device.

### BACKGROUND

In the related art, an OLED (Organic Light-Emitting Diode), as an emerging and strong rising light-emitting device, is widely used in the field of mobile display, due to the self-luminous, high contrast, and flexibility of the OLED. For terminal displays represented by mobile phones, those with ultra-high screen ratio and four curved surfaces will be the focus of competition for future display screens.

A four curved-surface screen refers to a display screen where the left, right, upper, and lower borders are bent to one side of the screen with a certain curvature radius. The four curved-surface screen has a beautiful appearance, is quite smooth for gripping, and can achieve an ultra-high screen ratio when viewed in front. However, in the design of the cover plate of the four curved-surface screen, a curved surface with a certain spherical angle is formed at the four corner area where the curved surfaces intersect, and the stress and strain in these areas are unevenly distributed in the two-dimensional direction, showing anisotropy. Therefore, the anti-reflection film (such as a polarizer) attached to the cover plate would easily cause problems such as bonding wrinkles, insufficient contact, and gaps.

It should be noted that the information disclosed in above section is only for the purpose of enhancing the understanding of the background of the present disclosure, and thus can include information that does not constitute prior art already known to those of ordinary skill in the art.

### SUMMARY

According to one aspect of the present disclosure, a display cover plate is provided, which includes: an anti-reflection layer including an anti-reflection film and a first adhesive layer, wherein at least a portion of the anti-reflection film has a curved-surface shape, the anti-reflection film has a convex surface and a concave surface, and the first adhesive layer is located on a side of the convex surface of the anti-reflection film; and an injection layer located on a side of the first adhesive layer facing away from the anti-reflection film and formed through an injection molding process, wherein the injection layer has a curved-surface shape that matches with a curved-surface area of the anti-reflection film, the injection layer has a convex surface and a concave surface, and the concave surface of the injection layer faces toward the first adhesive layer.

According to any one of the display cover plates provided by the present disclosure, the display cover plate further includes at least one first substrate stacked on a side of the injection layer facing away from the anti-reflection layer; wherein the first substrate includes a first base film and a second adhesive layer, the first base film has a curved-surface shape that matches with the curved-surface area of the anti-reflection film, the first base film has a convex surface and a concave surface, the concave surface of the first base film faces toward the injection layer, and the second adhesive layer is located on a side of the concave surface of the first base film.

According to any one of the display cover plates provided by the present disclosure, the display cover plate further includes a hardened layer or an oleophobic layer, wherein the hardened layer or the oleophobic layer is located on a side of the convex surface of the first base film.

According to any one of the display cover plates provided by the present disclosure, the display cover plate further includes a hardened layer and an oleophobic layer, wherein the hardened layer is located on a side of the convex surface of the first base film, and the oleophobic layer is located on a side of the hardened layer facing away from the first base film.

According to any one of the display cover plates provided by the present disclosure, the display cover plate further includes at least one second substrate stacked between the anti-reflection layer and the injection layer; wherein the second substrate includes a second base film and a third adhesive layer, the second base film has a curved-surface shape that matches with the curved-surface area of the anti-reflection film, the second base film has a convex surface and a concave surface, the concave surface of the second base film faces toward the first adhesive layer, and the third adhesive layer is located on a side of the convex surface of the second base film.

According to any one of the display cover plates provided by the present disclosure, the display cover plate further includes an oleophobic layer located on a side of the convex surface of the injection layer.

According to any one of the display cover plates provided by the present disclosure, the display cover plate further includes a hardened layer located between the injection layer and the oleophobic layer.

According to any one of the display cover plates provided by the present disclosure, a thickness of the injection layer is greater than or equal to 200 microns and less than or equal to 700 microns.

According to any one of the display cover plates provided by the present disclosure, a rigid modulus of the injection layer is greater than or equal to 1 GPa.

According to any one of the display cover plates provided by the present disclosure, the display cover plate is a four curved-surface cover plate or a spherical crown cover plate.

According to any one of the display cover plates provided by the present disclosure, the anti-reflection film is a polarizer.

According to one aspect of the present disclosure, a method for manufacturing a display cover plate is provided, which includes: providing an anti-reflection film and forming an anti-reflection layer based on the anti-reflection film, wherein at least a portion of the anti-reflection layer has a curved-surface shape; providing a first base film and forming a first substrate based on the first base film, wherein at least a portion of the first substrate has a curved-surface shape; placing the anti-reflection layer and the first substrate in an injection mold, wherein a curved-surface area of the anti-reflection layer and a curved-surface area of the first substrate face each other, a convex surface of the first substrate is in contact with a convex mold of the injection mold, and a concave surface of the anti-reflection layer is in contact with a concave mold of the injection mold; and obtaining a display cover plate including an injection layer by performing injection molding between a concave surface of the first substrate and a convex surface of the anti-reflection layer.

According to any one of the methods provided by the present disclosure, forming the anti-reflection layer based on the anti-reflection film, wherein at least a portion of the anti-reflection layer has a curved-surface shape, includes: forming a first adhesive layer on a side of the anti-reflection film to obtain a planar anti-reflection layer; and shaping the planar anti-reflection layer through hot-pressure shaping to obtain the anti-reflection layer with at least a portion thereof having a curved-surface shape, wherein the first adhesive layer is located on a side of the convex surface of the anti-reflection layer.

According to any one of the methods provided by the present disclosure, forming the anti-reflection layer based on the anti-reflection film, wherein at least a portion of the anti-reflection layer has a curved-surface shape, includes: shaping the anti-reflection film through hot-pressure shaping to obtain the anti-reflection film with at least a portion thereof having a curved-surface shape; and forming a first adhesive layer on a side of a convex surface of the anti-reflection film to obtain the anti-reflection layer with at least a portion thereof having a curved-surface shape.

According to any one of the methods provided by the present disclosure, forming the anti-reflection layer based on the anti-reflection film, wherein at least a portion of the anti-reflection layer has a curved-surface shape, includes: forming a first adhesive layer on a side of the anti-reflection film; forming a second base film and a third adhesive layer sequentially on a side of the first adhesive layer facing away from the anti-reflection film to obtain a planar anti-reflection layer; and shaping the planar anti-reflection layer through hot-pressure shaping to obtain the anti-reflection layer with at least a portion thereof having a curved-surface shape.

According to any one of the methods provided by the present disclosure, after performing injection molding between the concave surface of the first substrate and the convex surface of the anti-reflection layer, the method further includes: peeling off the first substrate to obtain the display cover plate including the anti-reflection film and the injection layer.

According to any one of the methods provided by the present disclosure, after performing injection molding between the concave surface of the first substrate and the convex surface of the anti-reflection layer, the method further includes: forming a hardened layer and an oleophobic layer sequentially on a side of the convex surface of the first substrate.

According to one aspect of the present disclosure, a display module is provided, which includes a display panel and a display cover plate as described in the above aspect, wherein the display panel is located on a side of a concave surface of the display cover plate.

According to any one of the display modules provided by the present disclosure, the concave surface of the display cover plate has a flat-surface area and a curved-surface area, the display panel includes a flat-surface panel and a curved-surface panel; and the flat-surface panel is adhered to the flat-surface area, and the curved-surface panel is adhered to the curved-surface area.

According to one aspect of the present disclosure, a method for manufacturing a display module is provided, which includes: providing an anti-reflection film and forming an anti-reflection layer based on the anti-reflection film, wherein at least a portion of the anti-reflection layer has a curved-surface shape; providing a display panel, wherein the display panel includes a flat-surface panel and a curved-surface panel; adhering the flat-surface panel to a flat-surface area on a concave surface of the anti-reflection layer, and adhering the curved-surface panel to a curved-surface area on the concave surface of the anti-reflection layer; providing a first base film and forming a first substrate based on the first base film, wherein at least a portion of the first substrate has a curved-surface shape; placing the anti-reflection layer adhered with the display panel and the first substrate in an injection mold, wherein the curved-surface area of the anti-reflection layer and a curved-surface area of the first substrate face each other, a convex surface of the first substrate is in contact with a convex mold of the injection mold, and the display panel is in contact with a concave mold of the injection mold; and obtaining the display module including an injection layer by performing injection molding between a convex surface of the anti-reflection layer and a concave surface of the first substrate.

According to one aspect of the present disclosure, a display device is provided, which includes the display module as described in the above aspect.

It should be understood that the general description above and the detailed description in the following are only illustrative and explanatory, and do not limit the present disclosure.

### BRIEF DESCRIPTION OF THE DRAWINGS

The drawings herein, which are incorporated in and constitute a portion of this specification, illustrate embodiments consistent with the present disclosure and serve together with the specification to explain principles of the present disclosure. It is apparent that the drawings in the following description are only some embodiments of the present disclosure, and other drawings can be obtained based on the drawings by those of ordinary skill in the art without creative effort.

FIG. 1 is a schematic diagram of a cross-sectional structure of a display cover plate according to embodiments of the present disclosure.

FIG. 2 is a schematic diagram of an axis side structure of a display cover plate according to embodiments of the present disclosure.

FIG. 3 is a schematic diagram of an axis side structure of a display cover plate according to embodiments of the present disclosure.

FIG. 4 is a schematic diagram of an axis side structure of a display cover plate according to embodiments of the present disclosure.

FIG. 5 is a schematic diagram of a process for shaping an anti-reflection layer according to embodiments of the present disclosure.

FIG. 6 is a schematic diagram of a cross-sectional structure of an anti-reflection layer according to embodiments of the present disclosure.

FIG. 7 is a schematic diagram of a cross-sectional structure of a display cover plate with an auxiliary film layer according to embodiments of the present disclosure.

FIG. 8 is a schematic diagram of a cross-sectional structure of an auxiliary film layer according to embodiments of the present disclosure.

FIG. 9 is a schematic diagram of a process for peeling off an auxiliary film layer according to embodiments of the present disclosure.

FIG. 10 is a schematic diagram of a cross-sectional structure of a display cover plate according to embodiments of the present disclosure.

FIG. 11 is a schematic diagram of a cross-sectional structure of a display cover plate according to embodiments of the present disclosure.

FIG. 12 is a schematic diagram of a cross-sectional structure of a display cover plate according to embodiments of the present disclosure.

FIG. 13 is a schematic diagram of a cross-sectional structure of a display cover plate according to embodiments of the present disclosure.

FIG. 14 is a schematic diagram of a cross-sectional structure of a display cover plate according to embodiments of the present disclosure.

FIG. 15 is a schematic diagram of a cross-sectional structure of a display cover plate according to embodiments of the present disclosure.

FIG. 16 is a schematic diagram of a process for manufacturing a display cover plate according to embodiments of the present disclosure.

FIG. 17 is a schematic diagram of a process for shaping a first substrate according to embodiments of the present disclosure.

FIG. 18 is a schematic diagram of a cross-sectional structure of a first substrate according to embodiments of the present disclosure.

FIG. 19 is a schematic diagram of a process before injection molding of a display cover plate according to embodiments of the present disclosure.

FIG. 20 is a schematic diagram of a process after injection molding of a display cover plate according to embodiments of the present disclosure.

FIG. 21 is a schematic diagram of a cross-sectional structure of a display module according to embodiments of the present disclosure.

FIG. 22 is a schematic diagram of a top view structure of a display panel according to embodiments of the present disclosure.

FIG. 23 is a schematic flowchart of a method for manufacturing a display module according to embodiments of the present disclosure.

### REFERENCE NUMERALS

100. display module;
10. display cover plate; 20. display panel;
101. flat-surface area; 102. curved-surface area;
201. flat-surface panel; 202. curved-surface panel;
11. anti-reflection layer; 12. injection layer; 13. first substrate; 14. second substrate; 15. hardened layer; 16. oleophobic layer; 17. auxiliary film layer; 18. shaping mold; 19. injection mold;
111. anti-reflection film; 112. first adhesive layer;
111a, convex surface of anti-reflection film; 112a, convex surface of first adhesive layer;
12a. convex surface of injection layer; 12b. concave surface of injection layer;
131. first base film; 132. second adhesive layer;
131a, convex surface of first base film; 131b, concave surface of first base film;
141. second base film; 142. third adhesive layer;
141a, convex surface of second base film; 141b, concave surface of second base film;
171. auxiliary base film; 172. fourth adhesive layer;
191. concave mold; 192. convex mold.

### DETAILED DESCRIPTION

Example embodiments will now be described more fully with reference to the drawings. However, the example embodiments can be implemented in a variety of forms and should not be construed as being limited to the embodiments set forth herein. Rather, the provision of these embodiments makes the present disclosure comprehensive and complete and conveys ideas of the example embodiments in a comprehensive manner to those skilled in the art. The same reference numerals in the drawings indicate the same or similar structures, and thus their detailed description will be omitted. In addition, the drawings are only schematic illustrations of the present disclosure and are not necessarily drawn to scale.

Although relative terms such as “upper” and “lower” are used in this specification to describe a relative relationship of one component and another component, these terms are used in this specification only for convenience, for example, according to a direction of the example shown in the drawings. It will be appreciated that if the device illustrated is turned upside down, the component described as “upper” will become the “lower” component. When a certain structure is “on” another structure, it may mean that the certain structure is integrally formed on the other structure, or it may mean that the certain structure is “directly” arranged on the other structure, or that the certain structure is “indirectly” arranged on the other structure through yet another structure.

Terms “a”, “an”, “the”, “said” and “at least one” are used to indicate presence of one or more elements/components/etc. Terms “include” and “comprise” are used to indicate an open-ended inclusion, and mean presence of additional elements/components/etc., in addition to listed elements/components/etc. Terms “first”, “second”, “third”, etc., are used as markings only, instead of limiting the number of objects.

Embodiments of the present disclosure provide a schematic diagram of a structure of a display cover plate 10. As shown in FIG. 1, the display cover plate 10 includes an anti-reflection layer 11 and an injection layer 12. The anti-reflection layer 11 includes an anti-reflection film 111 and a first adhesive layer 112. The anti-reflection film 111 includes a curved-surface area (at least a part of the anti-reflection film 111 is of a curved-surface shape), and the anti-reflection film 111 has a convex surface and a concave surface. The first adhesive layer 112 is located on the side of the convex surface 111a of the anti-reflection film. The injection layer 12 is located on a side of the first adhesive layer 112 facing away from the anti-reflection film 111, and is formed through injection molding process. The injection layer 12 is of a curved-surface shape that matches with the curved-surface area of the anti-reflection film 111. The injection layer 12 has a convex surface and a concave surface, and the concave surface 12b of the injection layer faces toward the first adhesive layer 112.

In some embodiments of the present disclosure, a hard structured injection layer 12 is formed on the side of the convex surface 112a of the first adhesive layer through injection molding, thereby achieving the adhesion between the anti-reflection film 111 and the injection layer 12, and improving the structural strength of the display cover plate 10. As a result, the adhesion in the related technology which is between the curved anti-reflection film 111 and the curved protective layer (glass substrate, resin substrate, etc.) pre-manufactured is avoided, thereby reducing bonding wrinkles at the corners of the anti-reflection film 111, which result in gaps and insufficient contact, and improving the yield of the display cover plate 10. In addition, for the curved anti-reflection film 111, when the injection layer 12 is formed through the injection molding process, the injection material can effectively squeeze the anti-reflection layer 11, and then further shape the curved-surface area of the anti-reflection layer 11 under the cooperation with the injection mold 19, so as to reduce the size and/or shape requirements for the curved-surface shape of the anti-reflection layer 11 while ensuring the yield of the display cover plate 10.

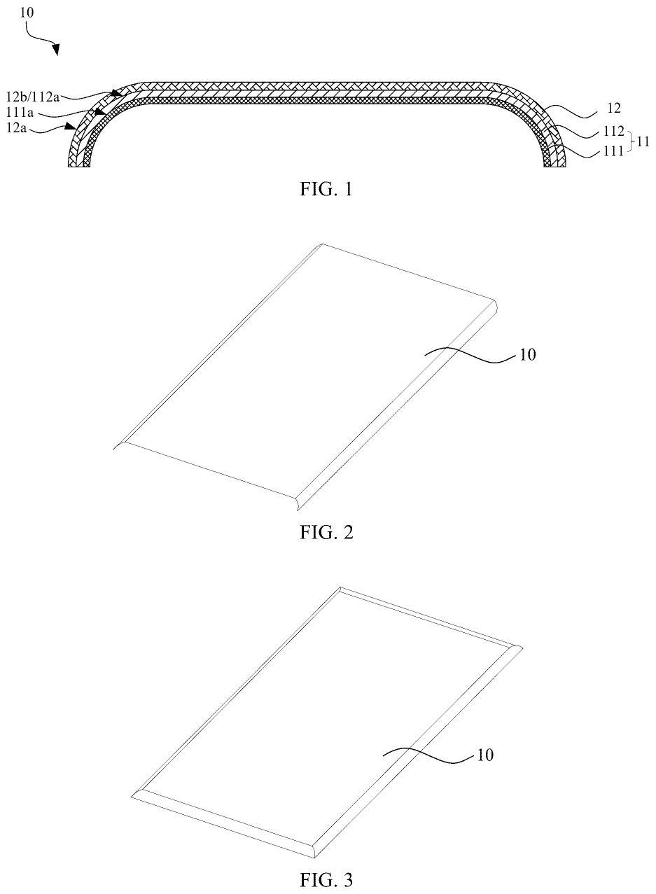

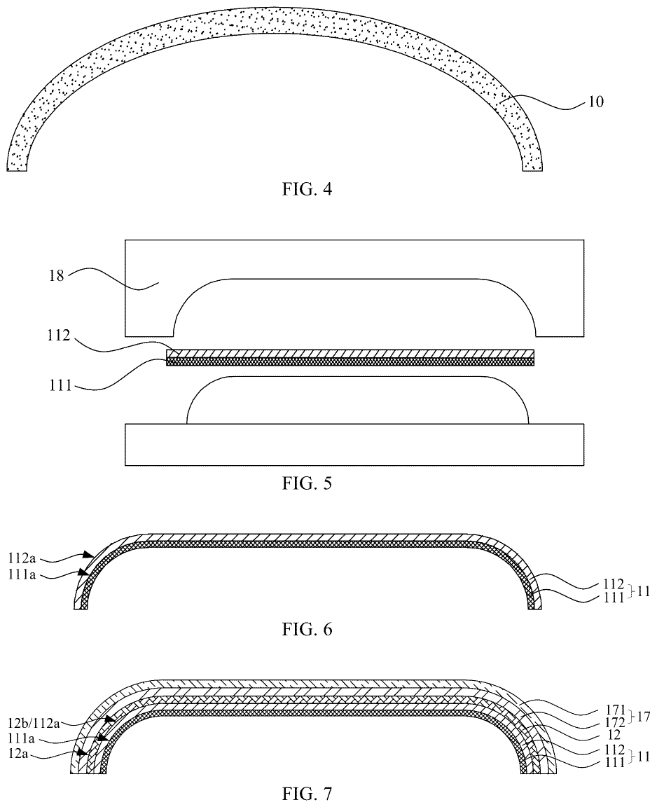

In some embodiments, the display cover plate 10 involved in the present disclosure can be a double curved-surface cover plate as shown in FIG. 2, a four curved-surface cover plate as shown in FIG. 3, or a spherical crown cover plate as shown in FIG. 4.

The anti-reflection film 111 can be a film layer with anti-reflection function such as a polarizer, and the anti-reflection film 111 has plasticity or stretchability to avoid bonding wrinkles at the corners when shaping the anti-reflection film 111. The first adhesive layer 112 can be OCA optical adhesive, OCR optical adhesive, hot melt adhesive, etc. The injection material of the injection layer 12 can be one or more of meltable materials such as polyimide, polyethylene terephthalate, polymethyl methacrylate, polyethylene naphthalate, polyurethane, etc. In some embodiments, the injection material of the injection layer 12 can also be other materials, as long as the materials can ensure that the injection layer 12 after injection has a certain structural strength, which is not limited in embodiments of the present disclosure.

In some embodiments, the thickness of the injection layer 12 is greater than or equal to 200 microns, and less than or equal to 700 microns. As a result, for the injection layer 12 with a certain structural strength, the maximum thickness of the injection layer 12 is limited to achieve the lightening and thinning of the display cover plate 10, and at the same time, the minimum thickness of the injection layer 12 is limited to ensure the structural strength of the injection layer 12, thereby ensuring the structural strength of the display cover plate 10. In some embodiments, the thickness of the injection layer 12 can be 200 microns, 250 microns, 300 microns, 350 microns, 400 microns, 500 microns, 600 microns, or 700 microns.

In some embodiments, the rigidity modulus of the injection layer 12 is greater than or equal to 1 GPa, so as to ensure the structural strength of the injection layer 12, thereby ensuring the structural stability of the display cover plate 10. In some embodiments, the rigidity modulus of the injection layer 12 is 1 GPa, 2 GPa, 3 GPa, 4 GPa, 5 GPa, or 6 GPa.

For the above anti-reflection layer 11, an anti-reflection film 111 can be first placed in a shaping mold 18 (such as a hot-pressure shaping mold, a high-pressure shaping mold, etc.) to shape the anti-reflection film 111 into a curved-surface shape, and then a first adhesive layer 112 can be coated or adhered on the side of the convex surface 111a of the anti-reflection film being shaped, to obtain the curved anti-reflection layer 11. In some embodiments, as shown in FIG. 5, a first adhesive layer 112 is first coated or adhered on one side of the anti-reflection film 111, and then the anti-reflection film 111 and the first adhesive layer 112 are placed as a whole in the shaping mold 18, so as to shape them into a curved-surface shape, and to obtain the anti-reflection layer 11 including a curved-surface area (at least apportion of the anti-reflection layer 11 has a curved-surface shape) as shown in FIG. 6.

In some embodiments, when the anti-reflection film 111 and the first adhesive layer 112 are placed as a whole in the shaping mold 18 for shaping, a side of the first adhesive layer 112 facing away from the anti-reflection film 111 is provided with a release paper, to avoid the fact that the first adhesive layer 112 is adhered to the shaping mold 18 and difficult to demold.

When the injection layer 12 is formed in the injection mold 19 through injection molding, the release paper on the first adhesive layer 112 is removed to obtain the injection layer 12 while achieving the adhesion between the injection layer 12 and the first adhesive layer 112, so as to reduce the process steps used for the display cover plate 10 and to improve the manufacturing efficiency of the display cover plate 10.

It should be noted that for the display cover plate 10 including the anti-reflection film 111 and the injection layer 12 described above, the injection modeling can be directly performed in the injection mold 19 based on the anti-reflection layer 11, so as to obtain the display cover plate 10 including the injection layer 12. In some embodiments, as shown in FIG. 7, a curved auxiliary film layer 17 can also be pre-manufactured, so that the injection modeling can be performed in the injection mold 19 based on the auxiliary film layer 17 and the anti-reflection layer 11, to obtain the display cover plate 10 including the anti-reflection film 111, the injection layer 12, and the auxiliary film layer 17. Then the auxiliary film layer 17 can be peeled off through a certain process.

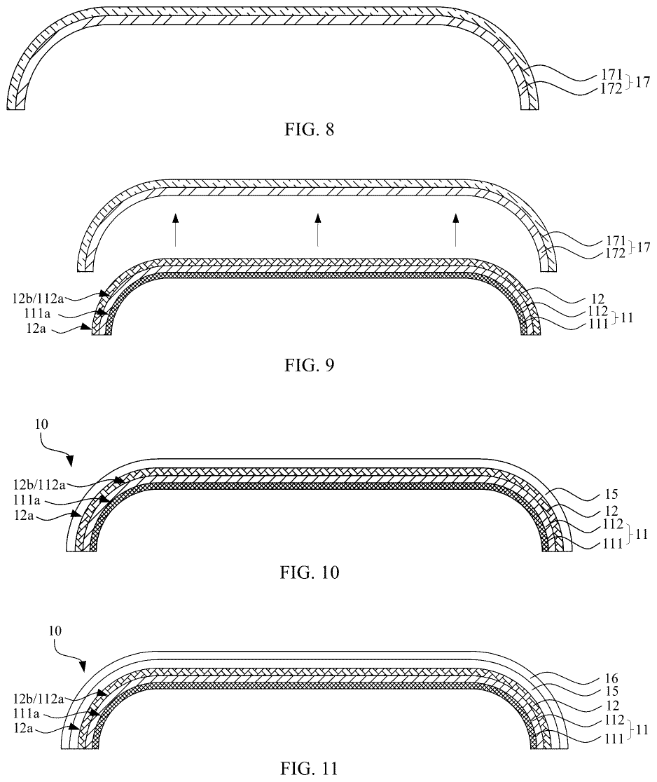

In some embodiments, as shown in FIG. 8, the auxiliary film layer 17 includes an auxiliary base film 171 and a fourth adhesive layer 172. The auxiliary base film 171 has a curved-surface shape that matches with the anti-reflection film 111, and the fourth adhesive layer 172 is located on the side of the concave surface of the auxiliary base film 171. Then the auxiliary film layer 17 and the anti-reflection layer 11 are placed in an injection mold 19 (including a concave mold 191 and a convex mold 192), the convex surface of the auxiliary film layer 17 is attached to the concave mold 191 of the injection mold 19, and the concave surface of the anti-reflection layer 11 is attached to the convex mold 192 of the injection mold 19. Then the injection molding is performed between the concave surface of the auxiliary film layer 17 and the convex surface of the anti-reflection layer 11 (i.e., between the first adhesive layer 112 and the fourth adhesive layer 172), to obtain the display cover plate 10 including the injection layer 12 and the auxiliary film layer 17, as shown in FIG. 7. Then as shown in FIG. 9, the auxiliary film layer 17 is peeled off to obtain the display cover plate 10 shown in FIG. 1.

In some embodiments, the auxiliary base film 171 can be a CPI base film, a PET film, ultra-thin glass, etc., as long as the auxiliary base film 171 has certain plasticity. That is, as long as the auxiliary base film 171 can be shaped into a curved-surface shape, and embodiments of the present disclosure do not limit this.

In some embodiments, the fourth adhesive layer 172 can be a UV anti-adhesive layer or the like, as long as it can facilitate the detachment of the auxiliary film layer 17 from the injection layer 12, and embodiments of the present disclosure do not limit this. Taking that the fourth adhesive layer 172 is a UV anti-adhesive layer as an example, after obtaining the injection layer 12 through the injection molding, the UV light can be used to irradiate the fourth adhesive layer 172, so that the fourth adhesive layer 172 lose its adhesive force, thereby facilitating the detachment of the auxiliary film layer 17 from the injection layer 12.

In some embodiments of the present disclosure, the display cover plate 10 including the injection layer 12 described above, further includes an oleophobic layer 16. The oleophobic layer 16 is located on the side of the convex surface 12a of the injection layer. In this way, by providing the oleophobic layer 16, the user's tactile experience can be improved, while it is conducive to ensuring the cleanliness of the display cover plate 10. The material of the oleophobic layer 16 and the method for manufacturing the oleophobic layer 16 can refer to relevant technologies, and embodiments of the present disclosure do not limit this.

In some embodiments, as shown in FIG. 10, the display cover plate 10 further includes a hardened layer 15, which is located on the side of the convex surface 12a of the injection layer. In this way, by providing the hardened layer 15, the structural strength of the display cover plate 10 can be further improved, and the occurrence of concave deformation of the display cover plate 10 under an external force can be reduced. The material of the hardened layer 15 and the method for manufacturing the hardened layer 15 can refer to relevant technologies, and embodiments of the present disclosure do not limit this.

In some embodiments, as shown in FIG. 11, the display cover plate 10 includes both an oleophobic layer 16 and a hardened layer 15. The hardened layer 15 is located on the side of the convex surface 12a of the injection layer, and the oleophobic layer 16 is located on a side of the hardened layer 15 facing away from the injection layer 12. In this way, by providing both the hardened layer 15 and the oleophobic layer 16, not only it is conducive to improving the user's tactile experience and ensuring the cleanliness of the display panel 20, but also it can further improve the structural strength of the display cover plate 10 and reduce the occurrence of concave deformation of the display cover plate 10 under an external force.

In some embodiments, the display cover plate 10 further includes at least one first substrate 13, and the at least one first substrate 13 is stacked on a side of the injection layer 12 facing away from the anti-reflection layer 11. In this way, by providing the at least one first substrate 13, the thickness of the protective layer of the display cover plate 10 is further increased, thereby improving the structural stability of the display cover plate 10.

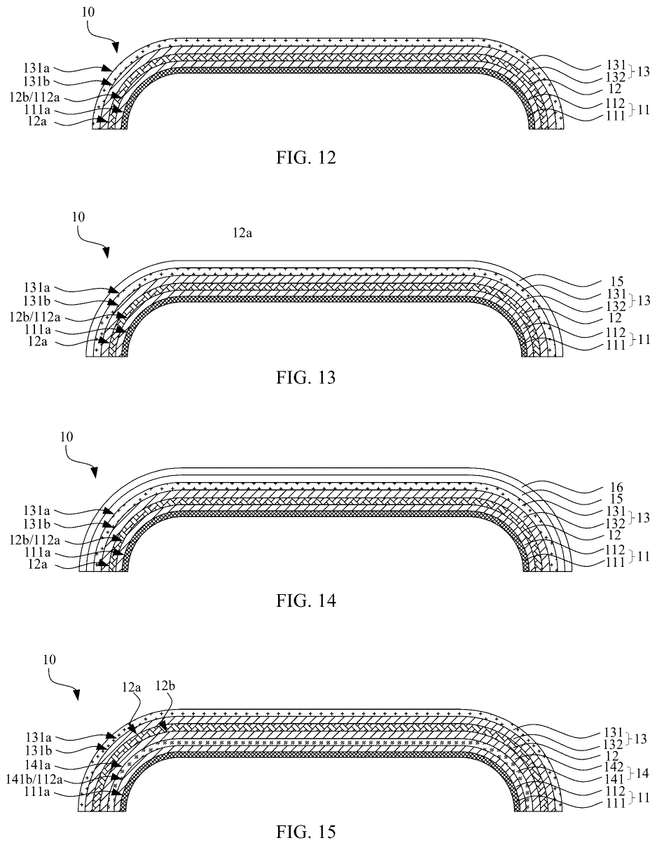

In some embodiments, in order to avoid a thick display device due to the assembly of a too thick display cover plate 10, a first substrate 13 is usually provided. As shown in FIG. 12, the display cover plate 10 includes a first substrate 13 stacked on the side of the injection layer 12 facing away from the anti-reflection layer 11.

In some embodiments, as shown in FIG. 12, the first substrate 13 includes a first base film 131 and a second adhesive layer 132. The first base film 131 has a curved-surface shape that matches with the curved-surface area of the anti-reflection film 111. The first base film 131 has a convex surface and a concave surface, the concave surface 131b of the first base film faces toward the injection layer 12, and the second adhesive layer 132 is located on the side of the concave surface 131b of the first base film.

In some embodiments, the film material of the first base film 131 can be the same or can be different from the film material of the auxiliary base film 171, and the material of the second adhesive layer 132 can be the same or can be different from the material of the first adhesive layer 112 mentioned above. Embodiments of the present disclosure do not limit this.

The method for manufacturing the first substrate 13 can refer to the method for manufacturing the anti-reflection layer 11 described above. The methods for manufacturing the two can be the same or different, and embodiments of the present disclosure do not limit this. In some embodiments, the second adhesive layer 132 is first coated or adhered on one side of the first base film 131, and then the first base film 131 and the second adhesive layer 132 are placed as a whole in the shaping mold 18 to shape them into curved-surface shapes, so as to obtain the curved anti-reflection layer 11.

In some embodiments of the present disclosure, the display cover plate 10 including the first substrate 13 as described above, further includes an oleophobic layer 16. The oleophobic layer 16 is located on the side of the convex surface 131a of the first base film. In this way, by providing the oleophobic layer 16, the user's tactile experience can be improved, while it is conducive to ensuring the cleanliness of the display cover plate 10. The material of the oleophobic layer 16 and the method for manufacturing the oleophobic layer 16 can refer to relevant technologies, and embodiments of the present disclosure do not limit this.

In some embodiments, as shown in FIG. 13, the display cover plate 10 further includes a hardened layer 15, which is located on the side of the convex surface 131a of the first base film. In this way, by providing the hardened layer 15, the structural strength of the display cover plate 10 can be further improved, and the occurrence of concave deformation of the display cover plate 10 under an external force can be reduced. The material of the hardened layer 15 and the method for manufacturing the hardened layer 15 can refer to relevant technologies, and embodiments of the present disclosure do not limit this.

In some embodiments, as shown in FIG. 14, the display cover plate 10 includes both an oleophobic layer 16 and a hardened layer 15. The hardened layer 15 is located on the side of the convex surface 131a of the first base film, and the oleophobic layer 16 is located on a side of the hardened layer 15 facing away from the first base film 131. In this way, by providing both the hardened layer 15 and the oleophobic layer 16, not only it is conducive to improving the user's tactile experience and ensuring the cleanliness of the display panel 20, but also it can further improve the structural strength of the display cover plate 10 and reduce the occurrence of concave deformation of the display cover plate 10 under an external force.

In some embodiments, the display cover plate 10 further includes at least one second substrate 14, ant the at least one second substrate 14 is stacked between the anti-reflection layer 11 and the injection layer 12. In this way, by providing one or more second substrates 14, the thickness of the protective layer of the display cover plate 10 is further increased, thereby improving the structural stability of the display cover plate 10.

In some embodiments, in order to avoid a thick display device due to the assembly of a too thick display cover plate 10, a second substrate 14 is usually provided. As shown in FIG. 15, the display cover plate 10 includes a second substrate 14 stacked between the anti-reflection layer 11 and the injection layer 12.

In some embodiments, as shown in FIG. 15, the second substrate 14 includes a second base film 141 and a third adhesive layer 142. The second base film 141 has a curved-surface shape that matches with the curved-surface area of the anti-reflection film 111. The second base film 141 has a convex surface and a concave surface, the concave surface 141b of the second base film faces toward the first adhesive layer 112, and the third adhesive layer 142 is located on the side of the convex surface 141a of the second base film.

In some embodiments, the film material of the second base film 141 can be the same or can be different from the film material of the auxiliary base film 171, and the material of the third adhesive layer 142 can be the same or can be different from the material of the first adhesive layer 112 mentioned above. Embodiments of the present disclosure do not limit this.

It should be noted that since the second substrate 14 and the anti-reflection layer 11 are fixed through adherence, in order to avoid bonding wrinkles and other issues at the corners of the anti-reflection layer 11 when the curved second substrate 14 is adhered to the curved anti-reflection layer 11, the second substrate 14 and the anti-reflection layer 11 can be stacked first, and are then placed as a whole in the shaping mold 18 to form a curved-surface shape.

In some embodiments, after the second base film 141 and the anti-reflection layer 11 are stacked and placed as a whole in the shaping mold 18 to form a curved-surface shape, the third adhesive layer 142 is formed on the convex surface 141a of the second base film. In some embodiments, the third adhesive layer 142, the second base film 141, and the anti-reflection layer 11 can also be stacked in sequence first, and are then placed as a whole in the shaping mold 18 to shape them into a curved-surface shape. Embodiments of the present disclosure do not limit this.

It should be noted that when the display cover plate 10 includes the first substrate 13 and/or the second substrate 14, the thickness of the injection layer 12 can be appropriately reduced to avoid the overall thickness of the display cover 10 too great. In some embodiments, the thickness of the injection layer 12 can be greater than or equal to 150 microns, and less than or equal to 500 microns. The rigidity modulus of the injection layer 12 can also be adjusted appropriately. In some embodiments, the rigidity modulus of the injection layer 12 is greater than or equal to 0.5 GPa.

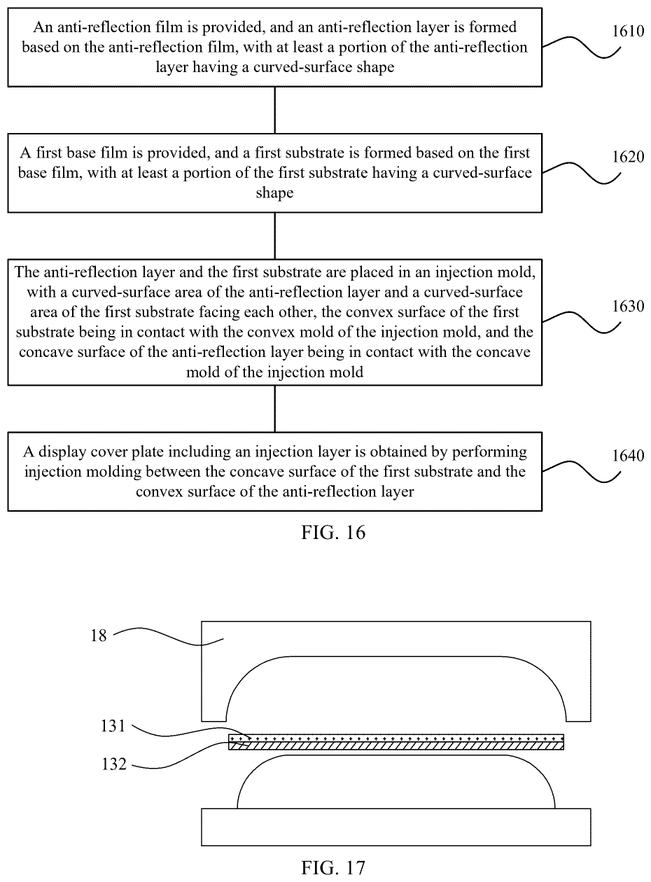

Embodiments of the present disclosure also provide a method for manufacturing a display cover plate. As shown in FIG. 16, the method includes the following steps S1610 to S1640.

In step S1610, an anti-reflection film is provided, and an anti-reflection layer is formed based on the anti-reflection film, with at least a portion of the anti-reflection layer having a curved-surface shape.

In step S1620, a first base film is provided, and a first substrate is formed based on the first base film, with at least a portion of the first substrate having a curved-surface shape.

In step S1630, the anti-reflection layer and the first substrate are placed in an injection mold, with a curved-surface area of the anti-reflection layer and a curved-surface area of the first substrate facing each other. The convex surface of the first substrate is in contact with the convex mold of the injection mold, and the concave surface of the anti-reflection layer is in contact with the concave mold of the injection mold.

In step S1640, a display cover plate including an injection layer is obtained by performing injection molding between the concave surface of the first substrate and the convex surface of the anti-reflection layer.

According to embodiments of the present disclosure, for the display cover plate manufactured through the above steps, the injection layer is formed between the anti-reflection layer and the first substrate through the injection molding, thereby avoiding the adhesion in the related technology which is between the curved anti-reflection film and the curved protective layer (glass substrate, resin substrate, etc.) pre-manufactured, reducing bonding wrinkles, insufficient contact, and gaps at the corners of the anti-reflection film, and improving the yield of the display cover plate. In addition, for the curved anti-reflection film, when the injection layer is formed through the injection molding process, the injection material can effectively squeeze the anti-reflection layer, and then further shape the curved-surface shape of the anti-reflection layer under the cooperation with the injection mold, so as to reduce the size and/or shape requirements for the curved-surface shape of the anti-reflection layer while ensuring the yield of the display cover plate.

In the above step S1610, specific film layers of the anti-reflection film can refer to the above embodiments, which will not be repeated here.

In some embodiments, the process of forming the anti-reflection layer, with at least a portion of which having a curved-surface shape, using the anti-reflection film can be as follows. As shown in FIG. 5, a first adhesive layer is formed on one side of the anti-reflection film, and a planar anti-reflection layer is thus obtained. Hot-pressure shaping is applied to the planar anti-reflection layer to shape the anti-reflection layer, the curved anti-reflection layer including a curved-surface area (at least a portion of the anti-reflection layer has a curved-surface shape) is obtained, and the first adhesive layer is located on the side of the convex surface of the anti-reflection layer.

The specific details of the first adhesive layer can refer to the above embodiments, and the first adhesive layer can be formed on one side of the anti-reflection film through adhesive bonding or coating. For the planar anti-reflection layer, high-pressure shaping, etc. can also be used, in addition to hot-pressure shaping, which will not be repeated in the present disclosure. When the planar anti-reflection layer is shaped using the hot-pressure shaping, a side of the first adhesive layer facing away from the anti-reflection film has the release paper, to prevent the first adhesive layer from sticking to the shaping mold during the hot-pressure shaping and affecting subsequent demolding.

In some embodiments, the hot-pressure shaping is applied to the anti-reflection film, and the curved anti-reflection film including a curved-surface area (at least a portion of the anti-reflection film has a curved-surface shape) is thus obtained. Then the first adhesive layer is formed on the side of the convex surface of the anti-reflection film, so as to obtain the curved anti-reflection layer including a curved-surface area (at least a portion of the anti-reflection layer has a curved-surface shape).

In some embodiments, for the planar anti-reflection film, high-pressure shaping, etc. can also be used, in addition to hot-pressure shaping. The specific details of the first adhesive layer can refer to the above embodiments, which will not be repeated in the present disclosure. Compared to the aforementioned embodiments, since the hot-pressure shaping is directly applied to the anti-reflection film to shape the anti-reflection film, the shaping effect of the anti-reflection layer will not be affected due to the presence of the release paper. After the shaping of the anti-reflection film is completed, the curved anti-reflection film is obtained, and the first adhesive layer can be formed on the convex surface of the anti-reflection film through coating.

In some embodiments, a first adhesive layer is formed on one side of the anti-reflection film, and a second base film and a third adhesive layer are sequentially formed on a side of the first adhesive layer facing away from the anti-reflection film, so as to obtain a planar anti-reflection layer. Hot-pressure shaping is then applied to the planar anti-reflection layer, and curved the anti-reflection layer including a curved-surface area (at least a portion of the anti-reflection layer has a curved-surface shape) is obtained.

In some embodiments, the first adhesive layer, the third adhesive layer, and the second base film can refer to the above embodiments, which will not be repeated in the present disclosure. By providing the second base film, the thickness of the protective layer of the display cover plate is further increased, thereby improving the structural stability of the display cover plate.

Based on the above embodiments, the third adhesive layer can be formed on the side of the convex surface of the first base film after the anti-reflection film, the first adhesive layer, and the first base film are stacked and the hot-pressure shaping has been applied. Alternatively, the third adhesive layer can be first formed on the side of the first base film facing away from the first adhesive layer and then be shaped through the hot-pressure shaping. Embodiments of the present disclosure do not limit this.

In the above step S1620, specific film layers of the first base film can refer to the above embodiments, which will not be repeated here.

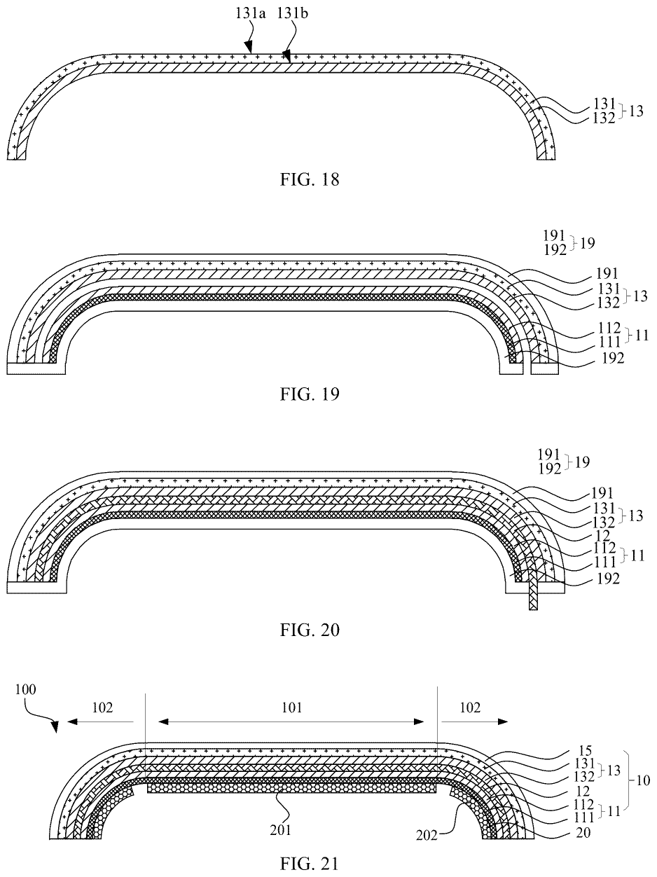

In some embodiments, the process of forming the first substrate, with at least a portion of which having a curved-surface shape, using the first base film can be as follows. As shown in FIG. 17, a second adhesive layer is formed on one side of the first base film, and a first substrate is thus obtained. Hot-pressure shaping is applied to the first substrate, the curved first substrate including a curved-surface area (at least a portion of the first substrate has a curved-surface shape) as shown in FIG. 18 is obtained.

The specific details of the second adhesive layer can refer to the above embodiments, and the second adhesive layer can be formed on one side of the first base film through adhesive bonding or coating. For the planar first substrate, high-pressure shaping, etc. can also be used, in addition to hot-pressure shaping, which will not be repeated in the present disclosure. When the planar first substrate is shaped using the hot-pressure shaping, a side of the second adhesive layer facing away from the first base film has the release paper, to prevent the second adhesive layer from sticking to the shaping mold during the hot-pressure shaping and affecting subsequent demolding.

In some embodiments, the hot-pressure shaping is applied to the first base film, and the curved first base film including a curved-surface area (at least a portion of the first base film has a curved-surface shape) is thus obtained. Then the first adhesive layer is formed on the side of the concave surface of the first base film, so as to obtain the curved first substrate including a curved-surface area (at least a portion of the first substrate has a curved-surface shape).

In some embodiments, for the planar first base film, high-pressure shaping, etc. can also be used, in addition to hot-pressure shaping. The specific details of the second adhesive layer can refer to the above embodiments, which will not be repeated in the present disclosure. Compared to the aforementioned embodiments, since the hot-pressure shaping is directly applied to the first base film to shape the first base film, the shaping effect of the first base film will not be affected due to the presence of the release paper. After the shaping of the first base film is completed, the curved first base film is obtained, and the second adhesive layer can be formed on the concave surface of the first base film through coating.

In the above step S1630, as shown in FIG. 19, the convex surface of the first substrate is in contact with the convex mold of the injection mold, and the concave surface of the anti-reflection layer is in contact with the concave mold of the injection mold, so as to form a space for accommodating the injection layer between the concave surface of the first substrate and the convex surface of the anti-reflection layer.

The injection material of the injection layer involved in the step S1640 can refer to the above embodiments, which will not be repeated here.

When forming the injection layer by performing the injection molding between the concave surface of the first substrate and the convex surface of the anti-reflection layer, the injection layer may overflow the injection hole of the injection mold. As shown in FIG. 20, an edge of the injection layer will inevitably protrude from an edge of the anti-reflection layer. In some embodiments, after the injection layer is obtained in step S1640, the method further includes removing, after the display cover plate including the injection layer is taken out from the injection mold, a protruding part of an edge of the injection layer at an edge of the display cover plate. In some embodiments, processes such as polishing, laser cutting, etc., are used to remove the protruding part of the edge of the injection layer.

In some embodiments, after the injection layer is obtained through the injection molding in step S1640, in order to achieve the lightening and thinning of the display cover plate while ensuring that the injection layer has a certain structural strength to meet the structural strength requirements for the display cover plate, the first substrate can be peeled off, so as to obtain a display cover plate that includes the anti-reflection film and the injection layer only.

In order to facilitate the peeling of the first substrate, the second adhesive layer included in the first substrate can refer to the fourth adhesive layer described in the above embodiments, that is, as long as it can facilitate the peeling of the first substrate from the injection layer. Embodiments of the present disclosure do not limit this.

In some embodiments, after the injection molding is performed between the concave surface of the first substrate and the convex surface of the anti-reflection layer, a hardened layer and/or an oleophobic layer can be formed on the side of the convex surface of the first substrate. By providing the hardened layer, the structural strength of the display cover plate can be further improved and the occurrence of concave deformation of the display cover plate under an external force can be reduced. By providing the oleophobic layer, the user's tactile experience can be improved while ensuring the cleanliness of the display cover plate.

It should be noted that when the display cover plate includes both the hardened layer and the oleophobic layer, the hardened layer is located on the side close to the first substrate, that is, after the injection layer is obtained in step S1640, the hardened layer and the oleophobic layer are sequentially formed on the side of the convex surface of the first substrate.

In some embodiments, after the first substrate is peeled off from the injection layer, a hardened layer and/or an oleophobic layer can be formed on the side of the convex surface of the injection layer. By providing the hardened layer, the structural strength of the display cover plate can be further improved and the occurrence of concave deformation of the display cover plate under an external force can be reduced. By providing the oleophobic layer, the user's tactile experience can be improved while ensuring the cleanliness of the display cover plate. When the display cover plate includes both the hardened layer and the oleophobic layer, the hardened layer is located on the side close to the injection layer, that is, after the injection layer is obtained in step S1640, the first substrate is peeled off from the injection layer, and then the hardened layer and the oleophobic layer are sequentially formed on the side of the convex surface of the injection layer.

It should be noted that although various steps of the method for manufacturing the display cover plate in the present disclosure are described in a specific order in the drawings, this does not require or imply that these steps must be executed in that specific order, or that all the steps shown must be executed to achieve the desired result. Additionally or alternatively, some steps can be omitted, multiple steps can be merged into one step for execution, and/or one step can be split into multiple steps for execution.

Embodiments of the present disclosure also provide a display module 100. As shown in FIG. 21, the display module 100 includes a display panel 20 and the module of the display cover plate 10 described in the above embodiments. The display panel 20 is located on the side of the concave surface of the display cover plate 10.

In some embodiments of the present disclosure, according to the display cover plate 10 described above, the display module 100 including the display cover plate 10 can avoid the adhesion in the related technology which is between the curved anti-reflection film 111 and the curved protective layer (glass substrate, resin substrate, etc.) pre-manufactured, thereby reducing bonding wrinkles, insufficient contact, and gaps at the corners of the anti-reflection film 111, which is conducive to improving the display effect and the service life of the display module 100.

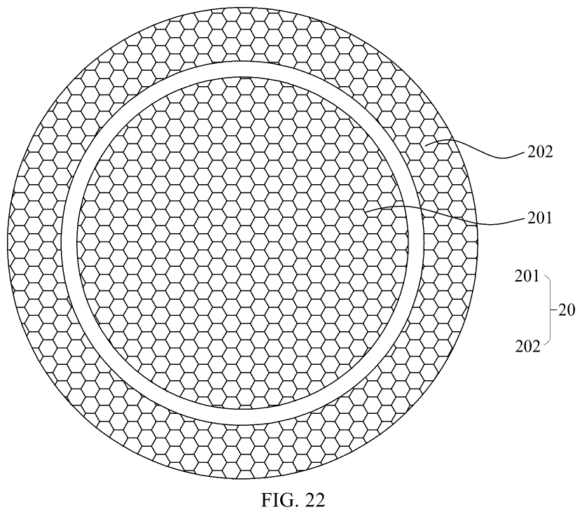

In some embodiments, as shown in FIGS. 21 and 22, the concave surface of the display cover plate 10 has a flat-surface area 101 and a curved-surface area 102, and the display panel 20 includes a flat-surface panel 201 and a curved-surface panel 202. The flat-surface panel 201 is adhered to the flat-surface area 101, and the curved-surface panel 202 is adhered to the curved-surface area 102. In this way, by adjusting the structure of the display panel 20 (including both the flat-surface panel 201 and the curved-surface panel 202), it is easier for the display panel 20 to adhere to the concave surface of the curved display cover plate 10, thereby improving the adhesion effect of the display panel 20 while ensuring the display effect of the display module 100.

In some embodiments, as shown in FIG. 22, the curved-surface panel 202 is formed as a ring-shaped structure, the flat-surface panel 201 is located in the inner ring of the curved-surface panel 202, and a gap is formed between the flat-surface panel 201 and the curved-surface panel 202.

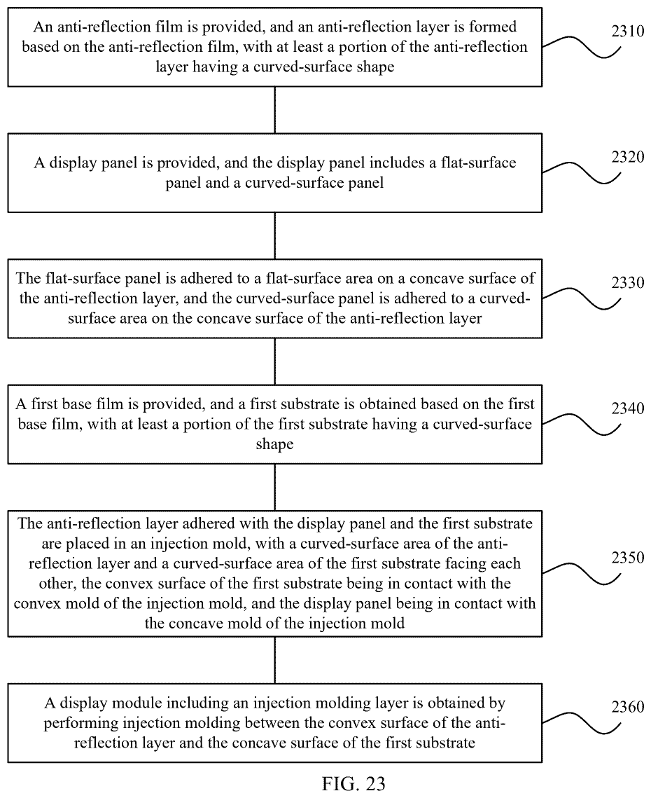

Embodiments of the present disclosure also provide a method for manufacturing a display module. As shown in FIG. 23, the method includes the following steps S2310 to S2360.

In step S2310, an anti-reflection film is provided, and an anti-reflection layer is obtained based on the anti-reflection film, with at least a portion of the anti-reflection layer having a curved-surface shape.

In step S2320, a display panel is provided, and the display panel includes a flat-surface panel and a curved-surface panel.

In step S2330, the flat-surface panel is adhered to a flat-surface area on a concave surface of the anti-reflection layer, and the curved-surface panel is adhered to a curved-surface area on the concave surface of the anti-reflection layer.

In step S2340, a first base film is provided, and a first substrate is obtained based on the first base film, with at least a portion of the first substrate having a curved-surface shape.

In step S2350, the anti-reflection layer adhered with the display panel and the first substrate are placed in an injection mold, with a curved-surface area of the anti-reflection layer and a curved-surface area of the first substrate facing each other. The convex surface of the first substrate is in contact with the convex mold of the injection mold, and the display panel is in contact with the concave mold of the injection mold.

In step S2360, a display module including an injection molding layer is obtained by performing injection molding between the convex surface of the anti-reflection layer and the concave surface of the first substrate.

In some embodiments of the present disclosure, when manufacturing the display module, the adhesion in the related technology which is between the curved anti-reflection film and the curved protective layer pre-manufactured can be avoided, thereby reducing bonding wrinkles, insufficient contact, and gaps at the corners of the anti-reflection film, which is conducive to improving the display effect and the service life of the display module.

In some embodiments, specific implementations of the above steps S2310, S2340 to S2360 can refer to embodiments of the present disclosure described above, which will not be repeated here, and specific implementations of the above steps S2320 and S2330 can refer to relevant technologies, and embodiments of the present disclosure do not limit this.

It should be noted that although various steps of the method for manufacturing the display module in the present disclosure are described in a specific order in the drawings, this does not require or imply that these steps must be executed in that specific order, or that all the steps shown must be executed to achieve the desired result. Additionally or alternatively, some steps can be omitted, multiple steps can be merged into one step for execution, and/or one step can be split into multiple steps for execution.

Embodiments of the present disclosure also provide a display device including the display module 100 described in the above embodiments. Based on the above embodiments, the display module 100 has a good display effect and a long service life. Therefore, the display device including the display module 100 also has a good display effect and a long service life, and can have a high user stickiness due to the good display effect.

After considering the specification and practicing of the invention disclosed herein, those skilled in the art will easily come up with other implementation solutions of the present disclosure. The present disclosure aims to cover any variations, uses, or adaptive changes of the present disclosure, which follow the general principles of the present disclosure and include common knowledge or commonly used technical means in the art that are not disclosed in the present disclosure. The specification and embodiments are only considered exemplary, and the true scope and spirit of the present disclosure are defined by appended claims.

1. A display cover plate, comprising:
an anti-reflection layer comprising an anti-reflection film and a first adhesive layer, wherein at least a portion of the anti-reflection film has a curved-surface shape, the anti-reflection film has a convex surface and a concave surface, and the first adhesive layer is located on a side of the convex surface of the anti-reflection film; and
an injection layer located on a side of the first adhesive layer facing away from the anti-reflection film and formed through an injection molding process, wherein the injection layer has a curved-surface shape that matches with a curved-surface area of the anti-reflection film, the injection layer has a convex surface and a concave surface, and the concave surface of the injection layer faces toward the first adhesive layer.

2. The display cover plate according to claim 1, further comprising at least one first substrate stacked on a side of the injection layer facing away from the anti-reflection layer;
wherein the first substrate comprises a first base film and a second adhesive layer, the first base film has a curved-surface shape that matches with the curved-surface area of the anti-reflection film, the first base film has a convex surface and a concave surface, the concave surface of the first base film faces toward the injection layer, and the second adhesive layer is located on a side of the concave surface of the first base film.

3. The display cover plate according to claim 2, further comprising a hardened layer or an oleophobic layer, wherein the hardened layer or the oleophobic layer is located on a side of the convex surface of the first base film.

4. The display cover plate according to claim 2, further comprising a hardened layer and an oleophobic layer, wherein the hardened layer is located on a side of the convex surface of the first base film, and the oleophobic layer is located on a side of the hardened layer facing away from the first base film.

5. The display cover plate according to claim 1, further comprising at least one second substrate stacked between the anti-reflection layer and the injection layer;
wherein the second substrate comprises a second base film and a third adhesive layer, the second base film has a curved-surface shape that matches with the curved-surface area of the anti-reflection film, the second base film has a convex surface and a concave surface, the concave surface of the second base film faces toward the first adhesive layer, and the third adhesive layer is located on a side of the convex surface of the second base film.

6. The display cover plate according to claim 1, further comprising an oleophobic layer located on a side of the convex surface of the injection layer.

7. The display cover plate according to claim 6, further comprising a hardened layer located between the injection layer and the oleophobic layer.

8. The display cover plate according to claim 1, wherein a thickness of the injection layer is greater than or equal to 200 microns and less than or equal to 700 microns.

9. The display cover plate according to claim 1, wherein a rigid modulus of the injection layer is greater than or equal to 1 GPa.

10. The display cover plate according to claim 1, wherein the display cover plate is a four curved-surface cover plate or a spherical crown cover plate, and the anti-reflection film is a polarizer.

11. (canceled)

12. A method for manufacturing a display cover plate, comprising:
providing an anti-reflection film and forming an anti-reflection layer based on the anti-reflection film, wherein at least a portion of the anti-reflection layer has a curved-surface shape;
providing a first base film and forming a first substrate based on the first base film, wherein at least a portion of the first substrate has a curved-surface shape;
placing the anti-reflection layer and the first substrate in an injection mold, wherein a curved-surface area of the anti-reflection layer and a curved-surface area of the first substrate face each other, a convex surface of the first substrate is in contact with a convex mold of the injection mold, and a concave surface of the anti-reflection layer is in contact with a concave mold of the injection mold; and
obtaining a display cover plate comprising an injection layer by performing injection molding between a concave surface of the first substrate and a convex surface of the anti-reflection layer.

13. The method according to claim 12, wherein forming the anti-reflection layer based on the anti-reflection film, comprises:
forming a first adhesive layer on a side of the anti-reflection film to obtain a planar anti-reflection layer; and
shaping the planar anti-reflection layer through hot-pressure shaping to obtain the anti-reflection layer with at least a portion thereof having a curved-surface shape, wherein the first adhesive layer is located on a side of the convex surface of the anti-reflection layer.

14. The method according to claim 12, wherein forming the anti-reflection layer based on the anti-reflection film, comprises:
shaping the anti-reflection film through hot-pressure shaping to obtain the anti-reflection film with at least a portion thereof having a curved-surface shape; and
forming a first adhesive layer on a side of a convex surface of the anti-reflection film to obtain the anti-reflection layer with at least a portion thereof having a curved-surface shape.

15. The method according to claim 12, wherein forming the anti-reflection layer based on the anti-reflection film, comprises:
forming a first adhesive layer on a side of the anti-reflection film;
forming a second base film and a third adhesive layer sequentially on a side of the first adhesive layer facing away from the anti-reflection film to obtain a planar anti-reflection layer; and
shaping the planar anti-reflection layer through hot-pressure shaping to obtain the anti-reflection layer with at least a portion thereof having a curved-surface shape.

16. The method according to claim 12, further comprising:
peeling off the first substrate to obtain the display cover plate comprising the anti-reflection film and the injection layer, after performing injection molding between the concave surface of the first substrate and the convex surface of the anti-reflection layer.

17. The method according to claim 12, further comprising:
forming a hardened layer and an oleophobic layer sequentially on a side of the convex surface of the first substrate, after performing injection molding between the concave surface of the first substrate and the convex surface of the anti-reflection layer.

18. A display module comprising a display panel and the display cover plate according to claim 1, wherein the display panel is located on a side of a concave surface of the display cover plate.

19. The display module according to claim 18, wherein the concave surface of the display cover plate has a flat-surface area and a curved-surface area, and the display panel comprises a flat-surface panel and a curved-surface panel; and
wherein the flat-surface panel is adhered to the flat-surface area, and the curved-surface panel is adhered to the curved-surface area.

20. A method for manufacturing a display module, comprising:
providing an anti-reflection film and forming an anti-reflection layer based on the anti-reflection film, wherein at least a portion of the anti-reflection layer has a curved-surface shape;
providing a display panel, wherein the display panel comprises a flat-surface panel and a curved-surface panel;
adhering the flat-surface panel to a flat-surface area on a concave surface of the anti-reflection layer, and adhering the curved-surface panel to a curved-surface area on the concave surface of the anti-reflection layer;
providing a first base film and forming a first substrate based on the first base film, wherein at least a portion of the first substrate has a curved-surface shape;
placing the anti-reflection layer adhered with the display panel and the first substrate in an injection mold, wherein the curved-surface area of the anti-reflection layer and a curved-surface area of the first substrate face each other, a convex surface of the first substrate is in contact with a convex mold of the injection mold, and the display panel is in contact with a concave mold of the injection mold; and
obtaining the display module comprising an injection layer by performing injection molding between a convex surface of the anti-reflection layer and a concave surface of the first substrate.

21. A display device comprising the display module according to claim 18.
